(19) United States
(12) Patent Application Publication
(10) Pub. No.: US 2005/0235184 A1
(43) Pub. Date: Oct. 20, 2005

(54) Semiconductor integrated circuit device and test method thereof

(75) Inventor: Hisashi Yamauchi, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 11/108,642

(22) Filed: Apr. 19, 2005

(30) Foreign Application Priority Data
Apr. 20, 2004 (JP) 2004-124661

(51) Int. Cl. G01R 31/28

(52) U.S. Cl. 714/726

(57) ABSTRACT

Disclosed is a semiconductor integrated circuit device using a scan path test in which propagation of an indefinite value to a test target path is inhibited while suppressing an increase in a circuit area, and a test method thereof. When a plurality of flip-flops within a logic circuit is serially connected to form scan chains and a scan path test is conducted, one or a plurality of flip-flops within the logic circuit are provided as indefinite state control flip-flops for holding values for preventing an indefinite value from propagating through a test target path and being captured by the scan chain on an output side during the test. The indefinite state control flip-flops are serially connected based on a control signal, and constitute a chain of flip-flops, different from the scan chain of other flip-flops. A value serially input from an input terminal is set in the plurality of indefinite state control flip-flops, respectively.

### FIELD OF THE INVENTION

The present invention relates to a semiconductor integrated circuit device and a test method thereof. More specifically, the invention relates to a scan path circuit and the test method thereof.

### BACKGROUND OF THE INVENTION

As an approach to design for testability of a semiconductor integrated circuit, a scan path test is employed. In this test, a plurality of flip-flops provided in a logic circuit are serially connected to operate as a shift register, thereby conducting the test. As is well known, a flip-flop that constitutes a scan path (also referred to as a “scan flip-flop”) includes a serial input terminal (SI), a data input terminal (D), a data output terminal (Q), a clock input terminal (C), and a scan mode control terminal (SMC). When a signal input to the scan mode control terminal (SMC) indicates a scan mode (also referred to as a “serial mode”), the flip-flop samples an input signal at the serial input terminal (SI) thereof responsive to a clock signal and outputs the sampled signal from the data output terminal (Q) thereof to the serial input terminal of a flip-flop in a subsequent stage, thereby forming a scan chain, which is a serial path in which a plurality of flip-flops are linked together. On the other hand, when the value of the scan mode control terminal (SMC) indicates a normal operation, the flip-flop samples a signal at the data input terminal (D) thereof in response to the clock signal, for output from the data output terminal (Q) thereof. At the time of the test, a test pattern is serially input from a scan input terminal (SCAN_IN)(also referred to as a “serial input terminal”) of the semiconductor integrated circuit and is sequentially set in flip-flops that constitute the scan chain on an input side. The output of the flip-flop in the scan chain on the input side is supplied to a circuit (combinational circuit) to be tested. By canceling the scan mode in this state to supply one clock pulse, the outputs of the circuit under test are sampled by the flip flops that constitute a scan chain on an output side in parallel. Then, the scan mode is set again, and the value of the scan chain on the output side is read out serially through the scan output terminal (SCAN_OUTPUT) terminal (also referred to as the “serial output terminal”) of the semiconductor integrated circuit for comparison with a readout expected value. The test is thereby conducted.

By the way, during the scan test in the semiconductor integrated circuit, when the circuit under test in the semiconductor integrated circuit includes a portion that will generate an indefinite value such as:
(A) a portion with a value thereof not fixed during the test
(B) a portion of which an operation does not need to be completed within a predetermined cycle during an actual
operation or the like, the indefinite value will be set in the scan chain on the output side.

As an example of the above-mentioned (A) portion, when the flip-flop of the scan chain on the output side receives the output of a RAM (random access memory), the flip-flop is set to an indefinite value unless the RAM is initialized.

Further, as an example of the above-mentioned (B) portion, when a path through which an operation will not be completed in one clock cycle can be pointed out. As described before, at the time of the test, the output of the circuit under test that has input the output of the scan chain on the input side is captured by the scan chain on the output side in one clock. For this reason, the indefinite value will be propagated to the scan chain on the output side connected to the path in the circuit under test, through which the operation will not be completed within one clock cycle.

Further, in a configuration in which signature compression is performed using an LFSR (Linear Feedback Shift Register) or the like, signature will be broken if entry of an indefinite value is made even during just one cycle, so that a match with the result of simulation (expected value) will not be obtained. More specifically, as described in Patent Document 1, when an approach to performing the signature compression on a result of the test using the LFSR is employed, it is necessary to add a control circuit so that the output of a portion that will generate an indefinite state during the test may not affect the result of the test. In the Patent Document 1, there is disclosed a configuration that allows normal signature generation on an indefinite value output from an unused functional block as well. In this configuration, an observation register circuit that performs the signature compression includes a register for storing mask information in the form of bits, and by forming a logical product between the value of this register and observed data by an AND circuit, entry and blocking of observed data is controlled. An indefinite value is thereby prevented from being captured by the observation register circuit.

On the other hand, a circuit is also known in which a configuration of a scan chain is changed, and the control circuit for inhibiting the influence of an indefinite value on the result of the test is not provided (refer to Patent Document 2, for example). FIG. 9 is a diagram showing a configuration disclosed in FIG. 1 of the Patent Document 2 and is cited for reference. As shown in FIG. 9, when a RAM 10 is not initialized, a data signal captured from a data output portion do[n] of the RAM 10 may include an indefinite value. In a configuration shown in FIG. 9, the data signal from the RAM 10 will not be transferred to an MISR (Multiple Input Signature Register) through a scan path 22. To the MISR, only a data signal DI[n] from a combinational circuit 40, captured by a scan path 13 is transferred to the MISR. A BIST (Built-In Self Test) of the combinational circuit 40 can be thereby performed without initialization of the RAM 10, under no influence of the indefinite value.

However, in the configuration in FIG. 9, the scan chain is branched into two on the way (that is, branched from a scan path 12 to scan paths 13 and 14), so that the configuration is an exceptional configuration different from a configuration of a normal scan path. Thus, there is a problem that a pattern automatically generated by an automatic test pattern generation (ATPG) tool cannot be employed without alteration, or the like.

A typical configuration provided with the control circuits for preventing propagation of an indefinite value to a test target path in a semiconductor integrated circuit that uses a scan path system will be described below, with reference to FIG. 8. FIG. 8 is created by the inventor of the present invention in order to describe a typical example provided with the control circuits for preventing propagation of the indefinite value to the test target path.

Referring to FIG. 8, flip-flops 103 to 108 are serially connected at the time of a test, thereby constituting a scan chain on an input side. Flip-flops 124, 123, and 122 are serially connected, thereby constituting a scan chain on an output side. A test pattern serially input from a serial input terminal (SIN1) is supplied to the flip-flops 103 to 108. Then, the outputs of a circuit under test are sampled by the flip-flops 124, 123, and 122, which constitutes the scan chain on the output side, in response to one clock. The sampled values at the flip-flops 122, 123, and 124 that constitute the scan chain on the output side are serially output one by one from a serial output terminal (SOUT2). In a test device or the like, comparison between serially output data with an expected value is made, or the signature compression is performed on the data for comparison between signature and the expected value, for example.

Referring to FIG. 8, AND gates 501, 502, and 503 are control circuits newly added for inhibiting propagation of the indefinite value to the test target path. The AND gate 501, for example, makes an output thereof low when a test mode signal/TESTMODE for controlling the test is active (low). A selector 119, which inputs the output of the AND gate 501 as a selection control signal (SEL), selects a path 111, for output to the data input terminal (D) of the flip-flop 122. That is, at the time of the test, the path 110 (output of a circuit group 114) is not selected by the selector 119. For this reason, capturing of the indefinite value by the flip-flop 122 is avoided.

Likewise, the AND gate 502 makes an output thereof low when the test mode signal/TESTMODE is active (low), thereby interrupting propagation from a path 112 to a circuit 118. Then, the AND gate 503 also makes an output thereof low when the test mode signal/TESTMODE is active (low), thereby interrupting propagation from the output of a RAM 120 to the flip-flop 124.

As described above, in a circuit configuration shown in FIG. 8, by fixing the test mode signal/TESTMODE to be active (low), the influences of all the portions which will generate indefinite values can be eliminated.

[Patent. Document 1]

Japanese Patent Kokai Publication No. JP-P2001-273159A (pp. 3-4, FIG. 1)

[Patent Document 2]

Japanese Patent Kokai Publication No. JP-A-11-352188 (pp. 6-7, FIG. 1)

### SUMMARY OF THE DISCLOSURE

However, in the case of the configuration in which the control circuits are added so as not to cause an indefinite value to influence the result of a test (refer to FIG. 8), there is a problem that due to the control circuits added, a circuit area will be increased.

On the other hand, when the control circuits for avoiding entry of an indefinite value to a scan path are not added, a scan chain becomes an exceptional configuration (refer to FIG. 9). Thus, pattern generation by the automatic test pattern (ATPG) was difficult.

The inventions disclosed in this application have the following general configurations:

In a semiconductor integrated circuit device according to one aspect of the present invention having a plurality of flip-flops in a logic circuit thereof, said flip-flops being serially connected based on a control signal to form a least a scan chain, and a test being performed, at least one flip-flop in the logic circuit is provided as an indefinite state control flip-flop that holds a value for preventing propagation of an indefinite value to a test target path during a test.

In the semiconductor integrated circuit device according to the present invention, a plurality of the indefinite state control flip-flops may be provided,
the indefinite state control flip-flops may be serially connected based on the control signal to constitute a serial chain different from the scan chains, and
a value serially input from an input terminal may be set in the indefinite state control flip-flops.

In the semiconductor integrated circuit device according to the present invention, one or more inversion circuits may be inserted on a portion of the serial chain that extend to each of the indefinite state control flip-flops so that the number of logic inversion on the portion of the serial chain becomes odd or even according to a value output by each of the indefinite state control flip-flops (however when the number of the logic inversion is zero, no inversion circuit is inserted because the inversion is not necessary). Then, a fixed value is supplied to the input terminal.

In the semiconductor integrated circuit device according to the present invention, the plurality of flip-flops that constitute the scan chains and the plurality of the indefinite state control flip-flops may be driven by a common clock signal.

In the semiconductor integrated circuit device according to the present invention, the control signal for controlling serial connection of the plurality of flip-flops constituting the scan chains and the control signal for controlling serial connection of the plurality of the indefinite state control flip-flops may be provided separately.

In the semiconductor integrated circuit device according to the present invention, the indefinite state control flip-flop performs control so that a path for propagating the indefinite value to the test target path is set to a fixed value, the test target path being arranged between the scan chains on input and output sides, or
propagation of the indefinite value is stopped in an intermediate position between starting and ending points of the test target path so that the indefinite value is not propagated to the flip-flops that constitutes the scan chain on the output side.

A scan path circuit according to other aspect of the present invention has a plurality of flip-flops serially connected based on a control signal to form scan chains, for conducting a test of a circuit between the scan chains on input and output sides. Then, at least one flip-flop is provided as an indefinite state control flip-flop that holds a value for preventing propagation of an indefinite value to a test target path during the test. In the scan path circuit according to the present invention, a plurality of the indefinite state control flip-flops are provided, and the plurality of the indefinite state control flip-flops are serially connected based on the control signal to constitute a serial chain different from the scan chains, and a value serially input from an input terminal is set in the plurality of the indefinite state control flip-flops serially connected.

A method of testing a semiconductor integrated circuit device according to one aspect of the present invention, the semiconductor integrated circuit device having a plurality of flip-flops within a logic circuit thereof serially connected based on a control signal to form scan chains, for conducting a test, the method including:
(A) selecting at least one flip-flop within the logic circuit as an indefinite state control flip-flop that holds a value for inhibiting propagation of an indefinite value to a test target path during the test; and
(B) conducting the test using the scan chains with the flip-flop set to the predetermined value.

In the test method according to the present invention, a plurality of the indefinite state control flip-flops may be provided, and the method may further include:
serially connecting the plurality of the indefinite state control flip-flops based on the control signal to form a second scan chain different from the scan chains; and
setting a value input from a serial input terminal in the plurality of the indefinite state control flip-flops.

In the test method according to the present invention, a fixed value is supplied to the serial input terminal, and one or more inversion elements are inserted on a portion of a shift path that extend from the serial input terminal to each of the plurality of the indefinite state control flip-flops so that the number of logic inversion on the portion of the serial chain becomes odd or even according to a logical value output by each of the indefinite state control flip-flops. Then, at the time of the test, the outputs of the plurality of the indefinite state control flip-flops are fixed.

In the test method according to the present invention, the indefinite state control flip-flop performs control so that a path for propagating the indefinite value to the path to be tested is set to a fixed value (the path is set to the fixed value that prevents the indefinite value from being output from the path), the path to be tested being arranged between the scan chains on input and output sides, or
propagation of the indefinite value is stopped in an intermediate position between starting and ending points of the path to be tested so that the indefinite value is not propagated to the flip-flops constituting the scan chain on the output side.

A test method according to other aspect of the present invention, with a plurality of flip-flops within a semiconductor integrated circuit serially connected based on a control signal to form scan chains, for conducting a scan path test, the method comprising:
(A) selecting from among flip-flops in a logic circuit flip-flops in which values for stopping propagation of an indefinite value to a test target path (referred to as “indefinite state control flip-flops”) during the test are set;
(B) serially connecting the indefinite state control flip-flops based on the control signal to be formed as a scan chain different from those of the other flip-flops; and
(C) conducting the test of the test target path by setting the values for stopping propagation of the indefinite value to the test target path in the indefinite state control flip-flops.

In the test method according to the present invention, the step of selecting the indefinite state control flip-flops (A) includes:
selecting a flip-flop located at the starting point of a predetermined path not targeted for the test (referred to as an “observation forbidden path”) as one of the indefinite state control flip-flops when the flip-flop is not located at the starting point of the test target path (referred to as an “observation path”).

In the test method according to the present invention, the step of selecting the indefinite state control flip-flops (A) includes:
retrieving from the logic circuit a flip-flop in which a value for stopping the propagation of the indefinite value in an intermediate position between starting and ending points of the observation path is set when a flip-flop located at the starting point of the observation path is identical to a flip-flop located at the starting point of the observation forbidden path; and
selecting the retrieved flip-flop as one of the indefinite state control flip-flops.

The test method according to the present invention may include:
inputting a fixed value to the input terminal when fixed value setting for the plurality of indefinite state control flip-flops is performed;
setting the number of times of logic inversion on the serial chain that extends from the input terminal to the indefinite state control flip-flop set to the same fixed value as the value at the input terminal to zero or even;
setting the number of times of the logic inversion on the serial chain that extends from the input terminal to the indefinite state control flip-flop set to a fixed value different from the value at the input terminal to be odd, thereby forming the serial chain; and
by setting a scan mode and shifting the fixed value from the input terminal, setting the fixed values in the plurality of indefinite state control flip-flops.

The meritorious effects of the present invention are summarized as follows.

According to the present invention, among the flip-flops in the logic circuit, flip-flops (indefinite state control flip-flops) for performing control for preventing propagation of an indefinite value to a test target path are selected. Then, the indefinite state control flip-flops are configured to form a chain different from those of normal scan flip-flops, and values for preventing the indefinite value from a portion that generates an indefinite state from propagating to the scan flip-flops are set in the indefinite state control flip-flops configured as this different chain. The influence of the indefinite value to the result of a test can be thereby avoided while an increase in the size of a circuit is suppressed, so that an accurate test can be thereby conducted.

Still other objects and advantages of the present invention will become readily apparent to those skilled in this art from the following detailed description in conjunction with the accompanying drawings wherein only the preferred embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a diagram showing an example of a circuit configuration according to an embodiment of the present invention;

FIG. 2 is a diagram showing a comparative example to which the present invention is not applied;

FIG. 3 is a diagram showing an example of a configuration that includes a compressor circuit;

FIG. 4 is a flow diagram showing an embodiment of a processing procedure for automatically designing a circuit according to the present invention;

FIGS. 5A and 5B are diagrams showing clock control in the embodiment of the present invention;

FIGS. 6A and 6B are diagrams showing a control method according to other embodiment of the present invention;

FIG. 7 is a diagram showing an example of a configuration circuit to which the control method according to the other embodiment of the present invention is applied;

FIG. 8 is a diagram for explaining a configuration in which propagation of an indefinite value to a scan chain is inhibited by control circuits; and

FIG. 9 is a diagram showing a configuration described in Patent Document 2 (FIG. 1).

### PREFERRED EMBODIMENTS OF THE INVENTION

In order to describe the present invention described above, embodiment of the present invention will be described below with reference to the appended drawings.

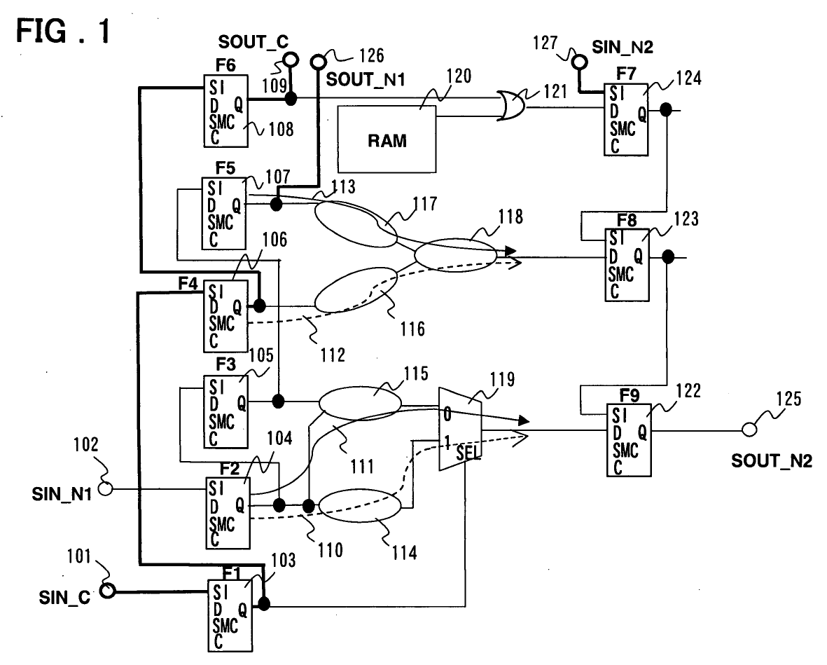

FIG. 1 is a diagram for explaining a configuration of an embodiment of the present invention. Referring to FIG. 1, flip-flops 104, 105, and 107 are serially connected when a scan mode control signal (SMC) indicates a scan mode. A path obtained by the serial connection constitutes a scan chain on an input side. Except for the time of the scan mode, each of the flip-flops 104, 105 and 107 performs a parallel operation in which a data signal at a data input terminal (D) thereof is sampled responsive to a clock signal from a clock input terminal (C) thereof for output from a data output terminal (Q) thereof.

Flip-flops 122, 123, and 124 are serially connected when the scan mode control signal (SMC) indicates the scan mode, and a path obtained by the serial connection constitutes a scan chain on an output side. Except for the time of the scan mode, each of the flip-flops 122, 123, and 124 performs a parallel operation in which the data signal at the data input terminal (D) thereof is sampled responsive to the clock signal from the clock input terminal (C) thereof, for output from the data output terminal (Q) thereof.

Further, flip-flops 103, 106, and 108 are serially connected when the scan mode control signal (SMC) indicates the scan mode, and perform control for inhibiting propagation of the value from a portion which generates an indefinite state through the data input terminals (D) of the flip-flops 124, 123, and 122. The flip-flops 103, 106, and 108 are referred to as “indefinite state control flip-flops” in this specification.

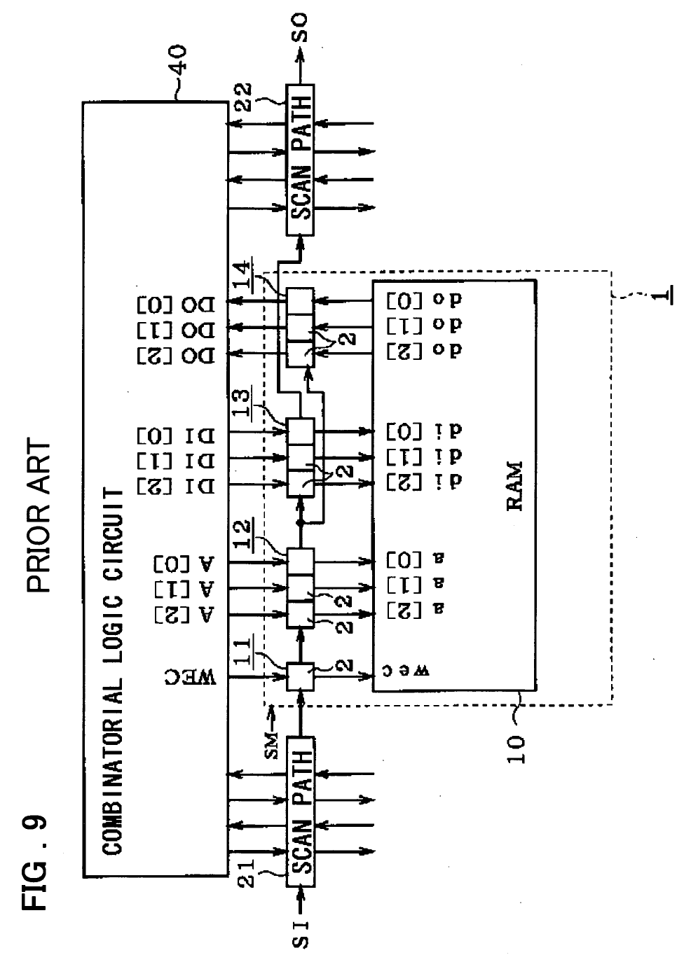

Between the scan chain on the input side and the scan chain on the output side, there are provided a RAM (random access memory) 120, an OR circuit 121, combinational circuits 114, 115, 116, 117, and 118, a selector (multiplexer) 119, paths 110, 111, 112, 113, and the like. At least one of these circuits and the paths constitutes a circuit under test to be tested by a scan path test. Referring to FIG. 1, the RAM 120 is illustrated as an example of a circuit of which an output value is not fixed during the test, as shown in FIG. 9.

As a brief description of connection between respective circuits in FIG. 1, a serial input terminal (SI) of the flip-flop (F2) 104 is connected to a scan input terminal (SIN_N1) 102 that constitutes the external terminal of a semiconductor integrated circuit, and the data output terminal (Q) thereof is connected to the combinational circuits 114 and 115 and is also connected to the serial input terminal (SI) of the flip-flop (F3) 105. The data output terminal (Q) of the flip-flop (F3) 105 is connected to the combinational circuit 115 and is also connected to the serial input terminal (SI) of the flip-flop (F5) 107. The data output terminal (Q) of the flip-flop (F5) 107 is connected to the combinational circuit 117, and is also connected to a scan output terminal 126. The serial input terminal (SI) of the flip-flop (F7) 124 is connected to a scan input terminal (SIN_N2) 127, and the data input terminal (D) of the flip-flop 124 is connected to the output of the OR circuit 121. The data output terminal (Q) of the flip-flop (F7) 124 is connected to the serial input terminal (SI) of the flip-flop (F8) 123. The data input terminal (D) of the flip-flop (F8) 123 is connected to the output of the combinational circuit 118, and the data output terminal (Q) of the flip-flop (F8) 123 is connected to the serial input terminal (SI) of the flip-flop (F9) 122. The data input terminal (D) of the flip-flop (F9) 122 is connected to the output of the selector 119, and the data output terminal (Q) thereof is connected to a scan output terminal (SOUT_N2) 125 that constitutes the external terminal of the semiconductor integrated circuit.

The serial input terminal (SI) of the flip-flop (F1) 103 is connected to a scan input terminal (SIN_C) 101 that constitutes the external terminal of the semiconductor integrated circuit, and the data output terminal (Q) thereof is connected to a selection control terminal SEL of the selector 119, and is also connected to the serial input terminal (SI) of the flip-flop (F4) 106. The data output terminal (Q) of the flip-flop (F4) 106 is connected to the combinational circuit 116 and is also connected to the serial input terminal (SI) of the flip-flop (F6) 108. The data output terminal (Q) of the flip-flop (F6) 108 is connected to a scan output terminal (SOUT_C) 109 that constitutes the external terminal of the semiconductor integrated circuit, and is also connected to the input terminal of the OR circuit 121. Sometimes is adopted such a circuit configuration in which outputs of a combinational circuit or the like not shown are supplied to data input terminals (D) of the flip-flops 103 to 108. Sometimes is adopted such a circuit configuration in which data output terminals (Q) of the flip-flops 122 to 124 are connected to a combinational circuit not shown. These configurations, are, however, omitted in FIG. 1.

Referring to FIG. 1, the paths 111 and 113 indicated by solid lines are the paths to be tested by a delay test (an AC test such as a propagation delay time measuring test, or a timing margin test), and are referred to as “observation paths” in the present specification. The paths 111 and 113 may be critical paths (the path that may generate an erroneous operation unless a signal is propagated within a specified time is referred to as a “critical path”).

Referring to FIG. 1, the paths 110 and 112 indicated by broken lines show the paths are not targeted for the test.

The paths 110 and 112 that are not targeted for the test are:
the paths that will not be used in an actual operation, or
the paths that cause no problem even if they change slowly in terms of a delay.

Since these paths will not be targeted for the delay test, these paths are referred to as “observation forbidden paths” in this specification. Though circuit connections are established in the paths 110 and 112, they are sometimes “false paths” in which no signal logically propagates.

As shown in FIG. 1, in the present embodiment, the indefinite state control flip-flops 103, 106, and 108 are configured to be serially connected as a chain different from that of the other flip-flops 104, 105, and 107. At the time of the test, the value of the flip-flop 103 is set so as to hold the value zero, flip-flop 106 is set so as to hold the fixed value of zero or one, and flip-flop 108 is set so as to hold the value of one.

In the embodiment of the present invention, respective values are set in the indefinite state control flip-flops 103, 106, and 108 before execution of a scan path test. Then, at the time of the scan path test, no clock is supplied to the indefinite state control flip-flops 103, 106, and 108, so that the flip-flops 103, 106, and 108 hold the set values. That is, referring to FIG. 1, at the time of the scan path test, a clock signal is supplied to the flip-flops 104, 105, 107, and 122 to 124, alone.

With the settings described above, during the test, the selector 119 always selects the observation path 111, thereby inhibiting propagation of an indefinite state to the flip-flop 122. More specifically, the value of the path 110 not targeted for the test is kept from having an influence on the input of the flip-flop 122.

Further, by setting the fixed value in the indefinite state control flip-flop 106 for the combinational circuit 116, propagation of the indefinite state from the combinational circuit 118 to the flip-flop 123 is inhibited. That is, by setting the fixed value in the indefinite state control flip-flop 106, propagation of an indefinite value from the path 112 (not targeted for the test) to the combinational circuit 118 is inhibited, so that outputting of an indefinite value from the output of the combinational circuit 118 to the flip-flop 123 owing to the path 112 is avoided. For simplicity, one indefinite state control flip-flop 106 for inhibiting propagation of the indefinite state for the combinational circuit 116 is shown in FIG. 1. However, when a plurality of paths through which the indefinite state propagates is present for the combinational circuit 116, a configuration may be of course employed in which by the plurality of indefinite state control flip-flops serially connected, propagation of the indefinite state for the combinational circuit 116 is inhibited.

Further, the logic value “1” is input to the OR circuit 121 from the indefinite state control flip-flop 108, so that its output is made to be the logic value “1”. For this reason, the output of the RAM 120 is masked, thereby inhibiting propagation of the output of the RAM 120 (which becomes sometimes indefinite during the test) to the flip-flop 124.

During the test, the chain constituted from the indefinite state control flip-flops 103, 106, and 108 maintains the fixed value, so that it becomes possible to test circuits (the circuit 115 on the observation path 111 and the circuits 117 and 118 on the observation path 113) using scan chains formed by the flip-flops 104, 105, 107, 122, 123, and 124.

In FIG. 1, a configuration is shown in which the data output terminal (Q) of the flip-flop 107 at the end of the scan chain on the input side is connected to the scan output terminal (SOUT_N1) 126, and the serial input terminal (SI) of the flip-flop 124 in the first stage of the scan chain on the output side is connected to the scan input terminal (SIN_N2) 127. However, the data output terminal (Q) of the flip-flop 107 at the end of the scan chain on the input side may be of course connected to the serial input terminal (S1) of the flip-flop 124, thereby constituting one scan chain.

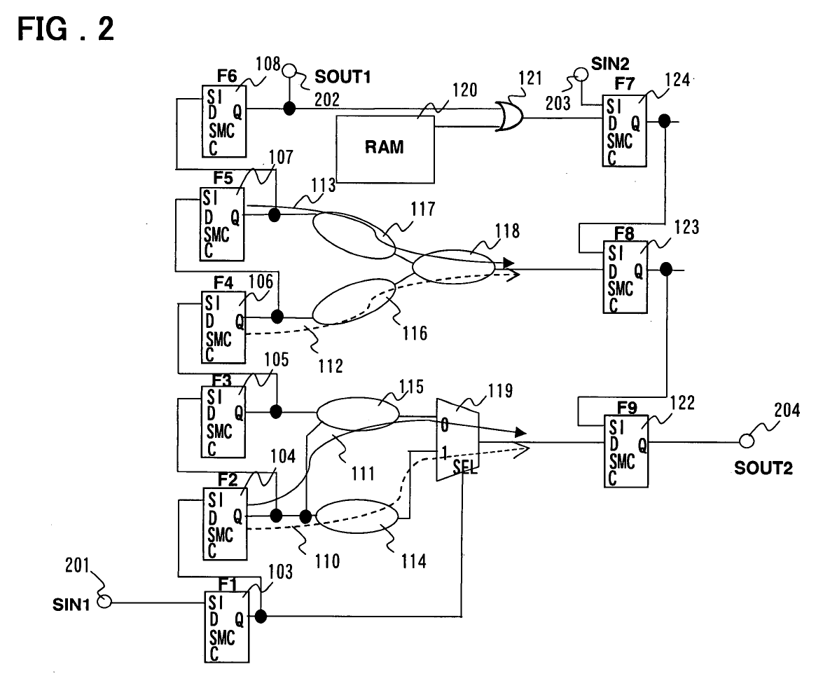

FIG. 2 shows, as a comparative example, a circuit configuration in a stage in which the present invention is not applied. Referring to FIG. 2, respective elements are shown, corresponding to those in FIG. 1. The flip-flops 103 to 108 that constitute a shift register for serially transferring a test pattern from a scan input terminal (SINI) 201 at the time of the scan mode, and the flip-flops 124, 123, and 122 that sample the outputs of a circuit under test in parallel and serially output the results of sampling are included. The RAM 120, OR circuit 121, selector 119, and combinational circuits 114, 115, and 116 to 118 are the same as those in the configuration shown in FIG. 1.

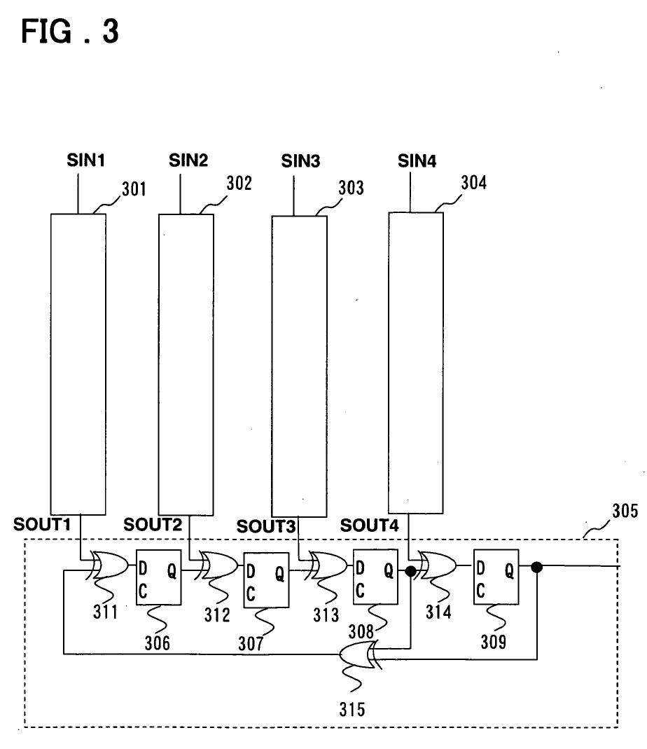

In the configuration shown in FIG. 2, when a pattern e.g. a pseudo random pattern such as an M series or the like is input from the scan input terminal (SINI) 201, the flip-flops 122 to 124 that constitute the scan chain on the output side sometimes sample indefinite values from the associated circuit under test at the time of the test, under the influence of the RAM 120 and the combinational circuits 114 and 116 (observation forbidden paths 110 and 112). An appropriate test cannot be thereby conducted. Especially when the result of the test (pass or fail) is determined through the circuit that collects the outputs of a plurality of scan chains 301 to 304, for compression and storage, as shown in FIG. 3, the entire result of the test becomes invalid if a flip-flop which receives an indefinite value is present in part of the configuration.

FIG. 3 is a diagram showing an example of the circuit (LFSR) that input the serial outputs of SOUT1, SOUT2, SOUT3, and SOUT4 from the plurality of scan chains 301 to 304, for compression. Incidentally, the configuration shown in FIG. 3 may also be provided in a semiconductor integrated circuit equipped with a BIST function. A compression unit 305 is configured to include four exclusive OR circuits (adders) each for inputting the output of an associated scan chain and the output of a D-type flip-flop in a preceding stage, and four D-type flip-flops that input the outputs of the exclusive OR circuits, connected in cascade. The output of an exclusive OR circuit 315 that inputs the outputs of a D-type flip-flop 308 in a third stage and a D-type flip-flop 309 in a fourth stage is fed back to an exclusive OR (XOR) circuit 311 in a first stage. The values (syndrome) stored in the flip-flops 306 to 309 at the time of completion of the test are compared with the result of simulation, thereby determining to be a pass/fail.

In the case of the comparative example shown in FIG. 2, if a cycle that makes the output of a scan chain indefinite is present, the values of the flip-flops 306 to 309 of the compression unit 305 become indefinite, so that the result of the test becomes invalid.

On contrast therewith, in the embodiment of the present invention shown in FIG. 1, the indefinite state control flip-flops 103, 106, and 108 constitute the chain different from other scan path. Then, by setting the input value to this scan path to a predetermined fixed value, propagation of an indefinite value to the flip-flops 122 to 124 is inhibited even if the pseudo random pattern or the like is input to the other scan path, for conducting the test. For this reason, according to the embodiment, when the compression unit 305 as shown in FIG. 3 is employed, the result of the test will not be invalid as in the comparative example.

The respect that is worthy of special mention in the present embodiment is that, compared with the comparative example shown in FIG. 2 (with no measures taken against propagation of an indefinite value), addition of elements becomes unnecessary. That is, according to this embodiment, the problem of area overhead will not be generated.

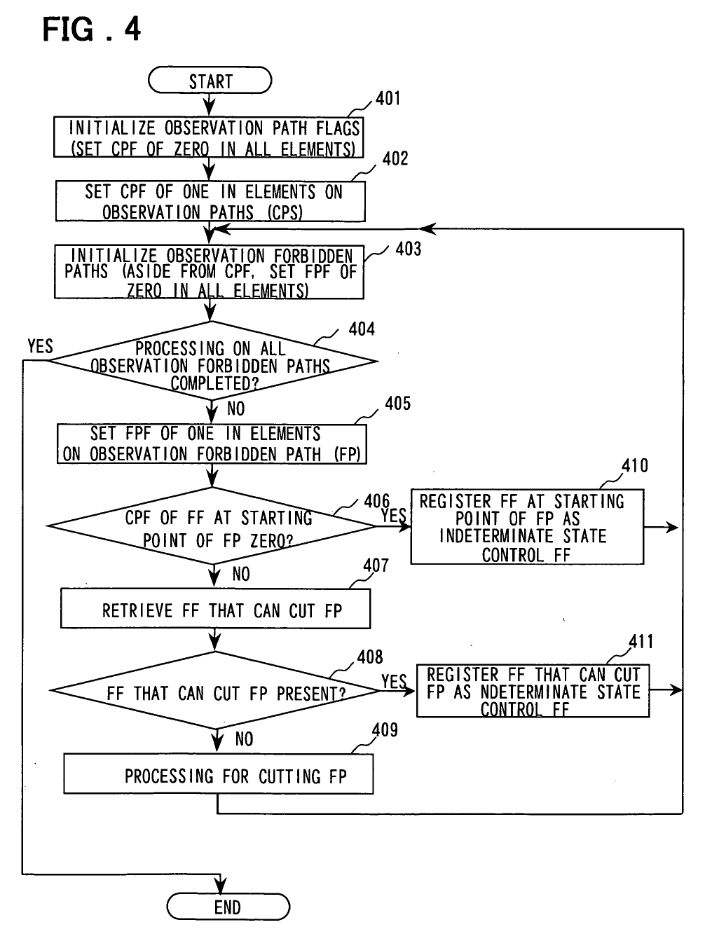

An embodiment of a processing procedure for selecting an indefinite state control flip-flop in the embodiment will be described with reference to FIG. 1. FIG. 4 is a flow diagram showing the embodiment of the procedure for determining the indefinite state control flip-flop in the embodiment of the present invention. In this embodiment, processing shown in FIG. 4 is executed by a design-automation device (a computer) for a semiconductor integrated circuit device. The circuit configuration information (circuit configuration information before the present invention is applied) as shown in FIG. 2, for example, is already stored in the storage device of the design-automation device.

Based on the circuit configuration information (including circuit connection information and element information, for example) stored in the storage device, the semiconductor integrated circuit is divided into circuit portions to be tested and circuit portions not to be tested. As described before, in the delay test, for example, a path to be tested is constituted from an observation path. Further, as described before, a path not to be tested is constituted from an observation forbidden path, and more specifically,
a path through which an indefinite value propagates, or
a path that is not used in an actual operation or causes no problem even if the path changes slowly in terms of a delay when the delay test is performed.

At step 401, observation path flags (or check path flags (termed as “CPFs”), which are the flags indicating observation paths, are initialized to zero. More specifically, of the circuit configuration information read out from the storage device on the computer that constitutes the design-automation device, the observation path flags (CPFs) of paths corresponding to the observation paths are set to zero. The path with the CPF value of zero is equivalent to the path not to be observed (not to be tested). The observation path flags are stored and managed as the attribute information of the paths.

At next step 402, the observation path flags of elements on the observation paths (or check paths) (termed as “CPs”) are set to one. More specifically, of the circuit configuration information read out from the storage device, the observation path flags (CPFs) provided as the attribute information of the elements on the observation paths are set to the value of one. That is, CPF=1 means that setting to “be observed” is performed.

At next step 403, observation forbidden path flags (termed as “FPFs”), which are the flags indicating observation forbidden paths, are initialized to zero. The observation forbidden path flags (FPFs) of all the elements on the circuit configuration information read out from the storage device are set to zero. FPF=0 is equivalent to “not forbidding the observation”.

Processing from step 404 through step 411 is basically the processing that is repeated in number corresponding to the number of all the observation forbidden paths on the circuit configuration information.

First, at step 404, it is determined whether the processing has been finished on all the observation forbidden paths on the circuit configuration information. When the processing has been finished on all the observation forbidden paths on the circuit configuration information, the processing is finished.

At step 405, the observation forbidden path flags (FPFs) of the elements on an observation forbidden path (also referred to as an “FP”) are set to one. FPF=1 is equivalent to “forbidding the observation”.

At next step 406, it is determined whether the flip-flop located at the starting point of the observation forbidden path (FP) is located at the starting point of the observation path (CP) (whether the observation path flag CPF of the flip-flop is zero or not).

When it is determined at step 406 that the flip-flop at the starting point of the observation forbidden path is not located at the starting point of the observation path (CPF=0) (branching to YES at step 406), the state of the flip-flop located at the starting point of this observation forbidden path (FP) is set to a fixed value. The logic operation of the observation forbidden path (FP) can be thereby fixed. For this reason, the operation proceeds to step 410, and the flip-flop at the starting point of the observation forbidden path (FP) is registered as an indefinite state control flip-flop.

On the other hand, when it is determined at step 406 that the observation path flag CPF of the flip-flop at the starting point of the observation forbidden path (FP) is one, the operation proceeds to step 407.

At step 407, a flip-flop that can cut the observation forbidden path (FP) for which the determination has been made at step 406 is retrieved. That is, in order to verify whether a flip-flop that can be set to cut the path that extends to the flip-flop on the observation forbidden path on the way, without cutting the observation path to which the element with the observation path flag (CPF) being one is connected is present or not, the circuit configuration information is searched for.

When it is verified at step 408 that the flip-flop that can be set to cut the observation forbidden path (FP) on the way without cutting the observation path is present, the operation proceeds to step 411, and this flip-flop is registered as the indefinite state control flip-flop.

On the other hand, when it is verified at step 408 that the flip-flop that can be set to cut the observation forbidden path (FP) on the way without cutting the observation path is not present, the operation proceeds to step 409, and a circuit change for cutting the observation forbidden path or the like is performed.

As an example of processing at step 407 described above, a flip-flop for an element for which only the observation forbidden flag FPF of one is present, or a flip-flop for which the observation path flag is not set and located at a starting point at a crossing between a path with the observation forbidden path flag FPF of one and an element with the observation path flag CPF of one, is retrieved. Then, by setting a fixed value to the output value of the flip-flop, it may be verified whether propagation of an indefinite value through the observation forbidden path stops or not.

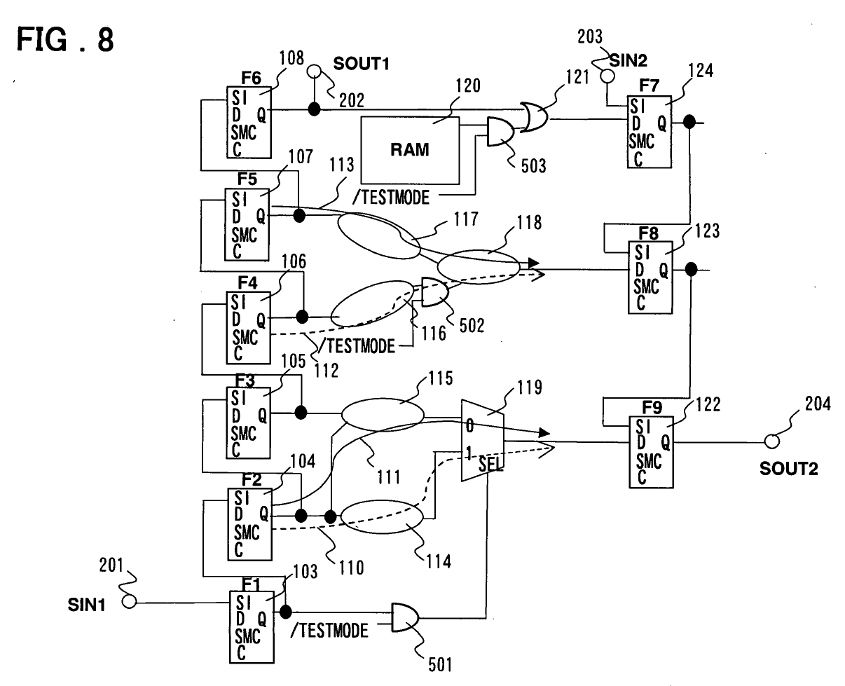

Further, when the result of the determination at step 408 is “NO” (accordingly, the result of the determination at step 406 is also “NO”), processing for adding an element so that the observation forbidden path can be logically cut off is performed. As shown in FIG. 8, for example, control circuits are added. However, in this case, circuit overhead increases, as described before. Thus, part of the observation paths may be excluded, and entire processing from step 401 may be performed again. It is because, by reducing the number of observation paths and increasing the number of observation forbidden paths to the contrary, the number of candidate flip-flops for indefinite state control flip-flops for performing control to prevent propagation of indefinite values to observation paths may be increased, and the number of candidate flip-flops that can be set to cut the observation forbidden paths (FPs) on the way may be increased.

Next, referring to FIG. 1, an application example of the processing procedure shown in FIG. 4 will be specifically described.

When the delay test is performed, the paths 111 and 113 are set to the observation paths (CPs), while the paths 110 and 112 are set to the observation forbidden paths (FPs).

First, at step 401, the observation path flags (CPFS) of all the elements in the circuit in FIG. 1 (all the elements in the circuit configuration information) are initialized to zero (that is, setting to be “not to be observed” is performed).

At next step 402, the observation path flags (CPFs) of the elements on the path 113 and the path 111 are set to one (that is, setting to “be observed” is performed).

Then, at step 403, the observation forbidden path flags (FPFs) of the entire circuit in FIG. 1 are initialized to zero.

In the circuit shown in FIG. 1, the observation forbidden paths (FPs) are two paths 112 and 110. However, at the point of time when the processing has been started, processing of the observation forbidden paths is not finished. Thus, the result of determination at step 404 becomes “NO”, so that the operation proceeds to step 405.

At step 405, the processing on the observation forbidden path 112 is first performed. That is, at step 405, the observation forbidden path flags (FPFs) of the elements provided on the observation forbidden path 112 are set to one.

Then, the determination at step 406 is performed. The flip-flop at the starting point of the observation forbidden path 112 is the flip-flop 106, and the observation path flag (CPF) of this flip-flop 106 is zero. For this reason, the result of the determination at step 406 becomes “YES”, so that the operation proceeds to step 410. At step 410, the flip-flop 106 is registered as the indefinite state control flip-flop.

Next, the operation is returned to step 403 again, and the observation forbidden path flags (FPFs) of all the elements in the circuit in FIG. 1 are initialized to zero.

The determination at step 404 is performed. Since the processing on the observation forbidden path 110 is not finished, the operation proceeds to step 405.

At step 405, the observation forbidden path flags (FPFs) of the elements provided on the observation forbidden path 110 are set to one.

Then, the determination at step 406 is performed. In this case, the flip-flop at the starting point of the observation forbidden path 110 is the flip-flop 104. Since the observation path flag (CPF) of this flip-flop 104 is one, the result of the determination at step 406 becomes “NO”, so that the operation proceeds to 407.

At step 407, the circuit is searched for to see whether a flip-flop that can cut the observation forbidden path 110 is present or not. In the circuit shown in FIG. 1, the flip-flop 103 is the flip-flop (not to be observed) with the observation path flag (CPF) being zero. Then, by setting the output value of this flip-flop 103 to zero, this flip-flop is determined as the flip-flop that can cut the observation forbidden path 110.

Then, the operation proceeds to the determination at step 408. Since the flip-flop 103 exists as the flip-flop that satisfies the condition (the flip-flop that can cut the observation forbidden path (FP) 110), the operation proceeds to step 411. At step 411 the flip-flop 103 is registered as the indefinite state control flip-flop.

Then, the operation is returned to step 403, and then proceeds to step 404. At this point of time, the processing on all the observation forbidden paths is finished. Thus, the processing is finished.

The foregoing description is the description of the processing about the delay test. The same processing can be performed for a logical operation test (functional test).

Referring to FIG. 1, when the RAM 120 is the circuit that becomes an indefinite state during the test, all the paths that extend to flip-flops with the RAM 120 regarded as the starting point are treated as observation forbidden paths. Referring to FIG. 1, only the path that extends to the flip-flop 124 through the OR circuit 121 is present as the output of the RAM 120. Thus, the path to the flip-flop 124 from the RAM 120 through the OR circuit 121 is set to the observation forbidden path.

In this case, the RAM 120 becomes the starting point. However, the RAM 120 is not a flip-flop, so that the determination at step 406 in FIG. 4 becomes “NO”.

In the processing at step 407 in FIG. 4 (for searching a flip-flop that can cut an observation forbidden path),
the flip-flop 108 does not have the observation path flag (with the observation path flag CPF being zero),
by fixing the output value of the flip-flop 108 at one, the path that extends to the flip-flop 124 from the RAM 120 through the OR circuit 121 can be cut.

Thus, the flip-flop 108 is registered as the indefinite state control flip-flop.

In the case of a circuit configuration shown in FIG. 1, the flip-flops 103, 106, and 108 are set to the indefinite state control flip-flops, and are controlled as a different scan chain from those of other flip-flops. This scan chain always needs to maintain the fixed value during the test. The scan chain to which the fixed value needs to be set during the test is referred to as a “scan chain C” in this specification so as to be differentiated from a scan path chain.

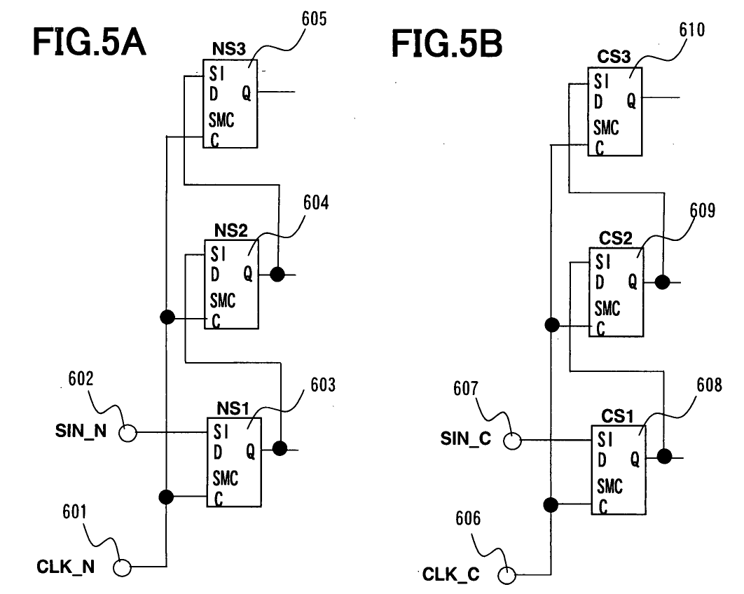

In this embodiment, a configuration as shown in FIGS. 5A and 5B, for example can be employed for the scan chain C as a configuration for being separated from the operation of other scan chains and setting the fixed value.

Referring to FIG. 5A, reference numerals 603, 604, and 605 denote flip-flops (NS1, NS2, NS3) for forming an ordinary scan path. Reference numeral 601 denotes an external clock input terminal (CLK_N), while reference numeral 602 denotes a scan input terminal (SIN_N).

Referring to FIG. 5B, reference numerals 608, 609, and 610 denote indefinite state control flip-flops (CS1, CS2, and CS3), reference numeral 606 is an external clock input terminal (CLK_C) different from the external clock input terminal (CLK_N), and reference numeral 607 is a scan input terminal (SIN_C). That is, the chain formed by serially connecting the indefinite state control flip-flops 608, 609, and 610 is the scan chain C.

In the present embodiment, the external clock input terminal (CLK_C) 606 is provided separately from the clock (CLK_N) for driving flip-flops of other scan chain (refer to FIG. 5A). Thus, before the test, by setting a fixed value in the scan chain C and then stopping the operation of the clock (CLK_C), a suitable operation can be performed. Different clocks are supplied to the flip-flops 603, 604, and 605 of the scan chain in FIG. 5A and the indefinite state control flip-flops 608, 609, and 610 of the scan chain C in FIG. 5B. By performing gate control over the same clock, control for stopping the clock supplied to the scan chain C can be performed. However, in this case, clock timing adjustment and the like will become bothering and difficult.

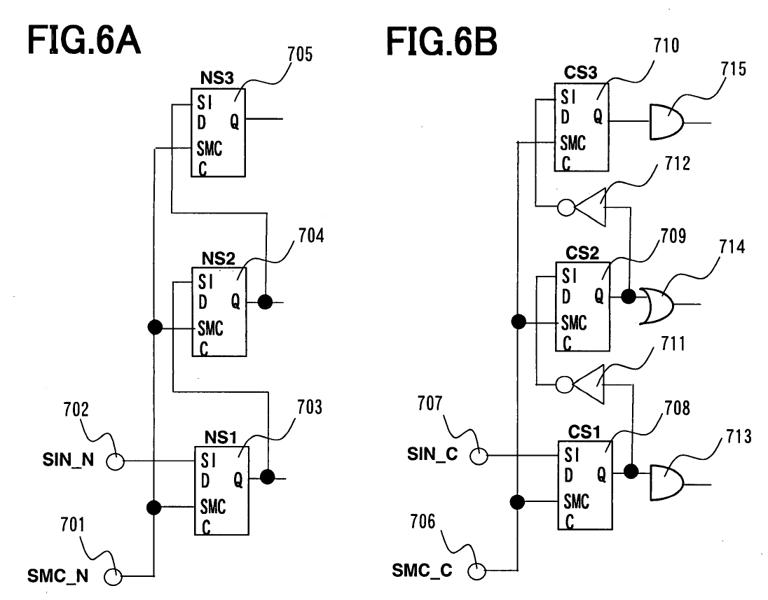

FIGS. 6A and 6B are diagrams showing a configuration of another embodiment of the present invention. Referring to FIG. 6(A), reference numerals 703, 704, and 705 denote flip-flops (NS1, NS2, and NS3), reference numeral 701 denotes an external input terminal (SMC_N) for a control signal that performs switching between the scan mode and a normal mode, and reference numeral 702 denotes a scan (serial) input terminal (SIN_N).

Referring to FIG. 6B, reference numerals 708, 709, and 710 denote indefinite state control flip-flops (CS1, CS2, and CS3), reference numeral 706 denotes an external input terminal (SMC_C) for a control signal that performs switching between the scan mode and the normal mode, and reference numeral 707 denotes a scan input terminal (SIN_C). Reference numerals 711 and 712 denote inverters. Reference numerals 713 and 715 denote AND gates, and reference numeral 714 denotes an OR gate.

Referring to FIG. 6B, the AND gate 713, OR gate 714, and AND gate 715 are all two-input gates, and one input terminals thereof are connected to the data output terminals (Q) of the indefinite state control flip-flops 708, 709, and 710, respectively. It is assumed that in an example shown in FIG. 6B, an indefinite value propagates through the other input terminals of the AND gate 713, OR gate 714, and AND gate 715.

As shown in FIGS. 6A and 6B, theses embodiments are effective when the clock for the scan chain C and the clock for other scan chain cannot be supplied separately unlike in FIGS. 5A and 5B. That is, in the configuration shown in FIGS. 6A and 6B, the common clock is supplied to the scan chain C in FIG. 6B and other scan chain shown in FIG. 6A.

In this case, when the flip-flops are set to the normal mode, the flip-flops capture values from the data input terminals (D) thereof. However, when the flip-flops maintain the scan mode and a fixed value is input to the scan input terminal (SIN_C) 707, fixed values are set in the respective flip-flops 708, 709, and 710 on the scan chain C.

When the fixed value supplied to the scan input terminal (SIN_C) 707 is zero at the time of the test, for the indefinite state control flip-flop in which zero needs to be set at the data output terminal (Q) thereof, it should be so configured that the number of times of logic inversion (the number of stages of inverters) on the path on the scan chain that extends to the flip-flop becomes even. For the indefinite state control flip-flop in which one needs to be set at the data output terminal (Q) thereof, it should be so configured that the number of times of the logic inversion (the number of inverters) on the path on the scan chain that extends to the flip-flop is odd.

In FIG. 6B, the indefinite value is propagated through the other input terminals of the AND gate 713, OR gate 714, and AND gate 715. In this case, by maintaining the output of the flip-flop 708 at zero, the output of the flip-flop 709 at one, and the output of the flip-flop 710 at zero, the AND gate 713, OR gate 714, and AND gate 715 output the fixed values zero, one, and zero, respectively. With this arrangement, indefinite value propagation can be stopped at the AND gate 713 of the indefinite state control flip-flop 708, OR gate 714 of the indefinite state control flip-flop 709, and AND gate 715 of the indefinite state control flip-flop 710.

When the fixed value applied to the scan input terminal (SIN_C) 707 is set to zero in this embodiment, the output of the flip-flop 708 is fixed at zero. Thus, it should be so adjusted that the even number of the inversions are made on the scan chain that extends to the output of the flip-flop 708. Herein, the inversion of zero times is made. Since it is so adjusted that the odd number of the inversions are made on the scan chain that extends to the output of the flip-flop 709 in order to fix the output of the flip-flop 709 at one, an inverter 711 is inserted, thereby making the logic inversion once.

In order to perform adjustment so that the even number of the inversions are made on the scan chain that extends to the output of the flip-flop 710 to fix the output of the flip-flop 710 at zero, an inverter 712 is inserted, thereby making the logic inversion two times.

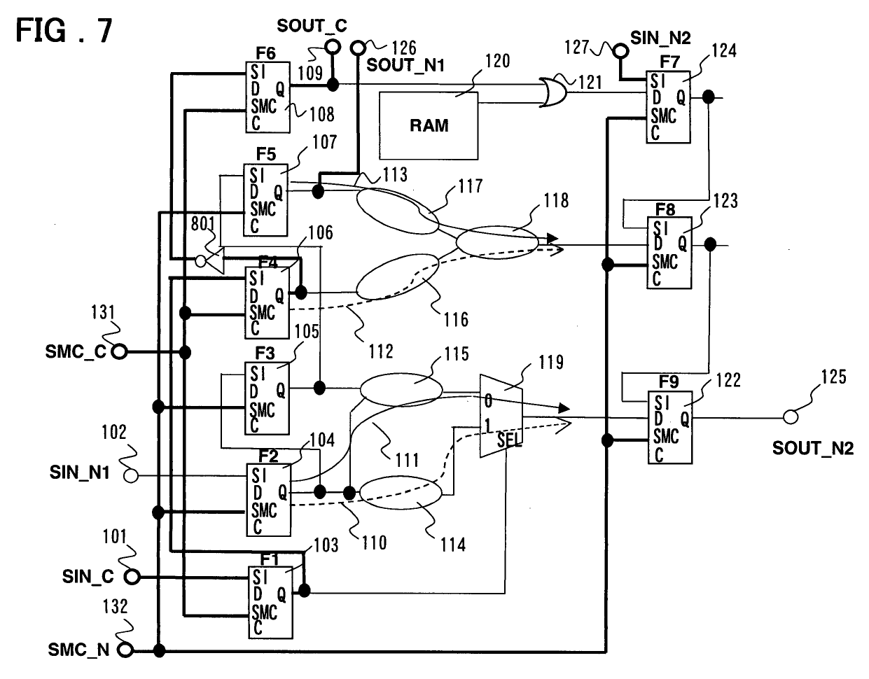

FIG. 7 is a diagram showing an example in which the configuration of this embodiment shown in FIGS. 6A and 6B are applied to the circuit configuration in FIG. 1. FIG. 7 shows a configuration in which the common clock is supplied to the scan chain C and other scan chains during the test in FIG. 1.

In the example shown in FIG. 7, as the scan mode control terminals (SMCs) for inputting the control signals that perform switching between the scan mode and the normal operation mode, a scan mode control terminal (SMC_C) 131 for the scan chain C and a scan mode control terminal (SMC_N) 132 for the other scan chains are provided separately. In the example shown in FIG. 7, the common clock signal is used for the scan chain C and the other scan chains.

For inhibiting propagation of an indefinite value to a test target path, the data output terminal (Q) of the indefinite state control flip-flop 103 needs to be set to the value zero, the data output terminal (Q) of the indefinite state control flip-flop 106 need to be set to a fixed value, and the data output terminal (Q) of the indefinite state control flip-flop 108 needs to be set to the value one.

The following description will be directed to a case in which the fixed value zero is supplied to the scan input terminal (SIN_C) 101. In this case, the number of the logic inversion on the serial chain that extends to the output of the flip-flop 103 needs to be set to be even. Thus, the number of the inversion is set to zero, and no inverter is inserted.

Since the number of the logic inversion on the serial chain that extends to the output of the flip-flop 108 needs to be set to be odd, the number of the inversion is set to one, and an inverter 801 is inserted.

According to the configuration shown in FIG. 7, even if the clock for the scan chain C is not stopped, by fixing the scan mode control terminal (SMC_C) 131 to the value indicating the scan mode, the output values of the flip-flops 103, 106, and 108 on the scan chain C can be fixed so as not to propagate an indefinite value.

Meanwhile, in FIG. 1, the scan input terminal (SIN_C) 101, scan input terminal (SIN_N1) 102, scan output terminal (SOUT_C) 109, scan output terminal (SOUT_N2) 125, scan input terminal (SIN_N2) 127, and scan output terminal (SOUT_N1) 126 may be the external terminals (pins) of the semiconductor integrated circuit device, or connection pads within a chip. When the compression unit 305 shown in FIG. 3 is provided within the chip, the scan output terminal (SOUT_N2) 125 for serially outputting the output of the scan chain on the output side is provided within the chip rather than as the external terminal. In this case, the pseudo random pattern generated within the chip may be serially supplied to the scan input terminal (SIN_N1) 102. On the other hand, when the scan input terminal (SIN_N1) 102, scan output terminal (SOUT_N2) 125, scan input terminal (SIN_C) 101, and the like are provided as the external terminals, a pattern from an LSI tester not shown is serially input to the scan input terminal (SIN_N1) 102, and a serial output from the scan output terminal (SOUT_N2) 125 is supplied to a comparator of the LSI tester, for comparison with an expected value. Further, the clock terminals 601 and 606 in FIGS. 5A and 5B and the scan mode control terminals 701 and 706 in FIGS. 6A and 6B may also be the external terminals (pins) of the semiconductor integrated circuit device, or the connection pads within the chip.

The foregoing description was given in connection with the embodiments described above. The present invention, however, is not limited to configurations of the embodiments described above, and of course includes various variations and modifications that could be made by those skilled in the art.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

1. A semiconductor integrated circuit device comprising a plurality of flip-flops in a logic circuit thereof, said flip-flops serially connected based on a control signal to form at least one scan chain, in order for a test to be conducted; and
at least one flip-flop provided in said logic circuit as an indefinite state control flip-flop that holds, during the test, a value for inhibiting propagation of an indefinite value to a path to be tested.

2. The semiconductor integrated circuit device according to claim 1, comprising a plurality of said indefinite state control flip-flops, wherein said indefinite state control flip-flops are serially connected based on the control signal to constitute a serial chain different from said scan chain; and
wherein a value serially input from an input terminal of said semiconductor integrated circuit is set to said indefinite state control flip-flops serially connected.

3. The semiconductor integrated circuit device according to claim 2, further comprising one or more inversion circuits, each receiving a signal and outputting an inverted signal of the signal received, inserted on respective associated portions of said serial chain, extending to each of said indefinite state control flip-flops so that a number of logic inversion on said portion of said serial chain becomes odd or even in accordance with a value output by each of said indefinite state control flip-flops.

4. The semiconductor integrated circuit device according to claim 3, wherein a plurality of flip-flops that constitute said scan chain and a plurality of said indefinite state control flip-flops are driven by a common clock signal.

5. The semiconductor integrated circuit device according claim 1, wherein said indefinite state control flip-flop performs control such that
a path for propagating the indefinite value to a test target path is set to a fixed value, the test target path arranged between a plurality of flip-flops constituting scan chains on input and output sides; or
propagation of the indefinite value is stopped in an intermediate position between starting and ending points of the test target path so that the indefinite value is not propagated to the flip-flops that constitutes a scan chain on the output side.

6. A scan path circuit including a plurality of flip-flops serially connected based on a control signal to form scan chains, for conducting a test of a circuit between said scan chains on input and output sides;
said scan path circuit comprising at least one flip-flop, different from said plurality of flip-flops constituting said scan chains, as an indefinite state control flip-flop that holds a value for inhibiting propagation of an indefinite value to a test target path during the test;
said indefinite state control flip-flop performing control such that the indefinite value is not input to the flip-flops constituting said scan chain on the output side connected to the test target path during the test.

7. The scan path circuit according to claim 6, comprising a plurality of said indefinite state control flip-flops, wherein said indefinite state control flip-flops are serially connected based on the control signal to constitute a serial chain different from said scan chains; and
wherein a value serially input from an input terminal of said scan path circuit is set to said plurality of indefinite state control flip-flops serially connected.

8. The scan path circuit according to claim 6, wherein said indefinite state control flip-flop performs control such that
a path for propagating the indefinite value to the test target path is set to a fixed value, said test target path arranged between said scan chains on input and output sides; or
propagation of the indefinite value is stopped in an intermediate position between starting and ending points of the test target path so that the indefinite value is not propagated to said scan chain on the output side.

9. The scan path circuit according to claim 7, further comprising one or more inversion circuits, each receiving a signal and outputting an inverted signal of the signal received, inserted on respective associated portions of said serial chain extending to each of said indefinite state control flip-flops, so that a number of logic inversion on said portion of said serial chain becomes odd or even according to a value output by each of said indefinite state control flip-flops.

10. A method of testing a semiconductor integrated circuit device having a plurality of flip-flops within a logic circuit thereof serially connected based on a control signal to form scan chains, for conducting a test of a circuit between said scan chains on input and output sides, said method comprising:
selecting at least one flip-flop within said logic circuit different from said plurality of flip-flops constituting said scan chains as an indefinite state control flip-flop that holds a value for inhibiting propagation of an indefinite value to a test target path during the test; and
conducting the test using said scan chains with said indefinite state control flip-flop set to the value.

11. The method according to claim 10, wherein there are provided a plurality of said indefinite state control flip-flop; and
wherein said method further comprises:
serially connecting a plurality of said indefinite state control flip-flops based on the control signal to form a serial chain different from said scan chains; and
setting a value serially input from an input terminal to a plurality of said indefinite state control flip-flops.

12. The method according to claim 10, wherein said indefinite state control flip-flop performs control such that
a path for propagating the indefinite value to the test target path is set to a fixed value, the test path arranged between said scan chains on input and output sides of said scan chains; or
propagation of the indefinite value is stopped in an intermediate position between starting and ending points of the test target path so that the indefinite value is not propagated to said scan chain on the output side.

13. The method according to claim 11, wherein, when value setting for a plurality of said indefinite state control flip-flops is performed, a fixed value is input from said input terminal, and for said indefinite state control flip-flop that is set to a same fixed value as the value at said input terminal, a number of times of logic inversion on the serial chain that extends from said input terminal to said indefinite state control flip-flop is set to zero or even;
for the indefinite state control flip-flop that is set to a fixed value different from the value at said input terminal, a number of times of the logic inversion on the serial chain that extends from said input terminal to the indefinite state control flip-flop is set to be odd, thereby forming said serial chain; and
by shifting the fixed value from said input terminal, said plurality of indefinite state control flip-flops are set to the values for inhibiting the indefinite value from propagating to the test target path.

14. The method according to claim 10, wherein the step of selecting said indefinite state control flip-flop selects a flip-flop located at a starting point of a predetermined path not targeted for the test (referred to as an “observation forbidden path”) as the indefinite state control flip-flop when the flip-flop is not located at a starting point of the test target path (referred to as an “observation path”).

15. The method according to claim 10, wherein the step of selecting the indefinite state control flip-flop includes:
retrieving from said logic circuit a flip-flop in which a value for stopping the propagation of the indefinite value in an intermediate position between starting and ending points of the observation path is set when a flip-flop located at the starting point of the observation path is identical to a flip-flop located at a starting point of the observation forbidden path; and
selecting the retrieved flip-flop as the indefinite state control flip-flop.

16. The method according to 10, wherein the test is conducted by latching an output of a logic circuit to be tested by a first flip-flop and reading out data latched by said first flip-flop, said logic circuit to be tested forming a path through which an input signal propagates;
wherein a desired fixed value is latched by a second flip-flop serving as said indefinite state control flip-flop so as to prevent an indefinite value being output from said logic circuit to be tested, the desired fixed value becoming a value of the input signal for said path; and
an output of the fixed value from said second flip-flop is supplied as the input signal to said path, for conducting the test.

17. The method according to 10, wherein the test is conducted by inputting to a first flip-flop an output of a circuit with an output logic value not fixed during the test through a logic gate, for latching, and reading out data latched by said first flip-flop; and
wherein, for conducting the test, other input value is latched by a second flip-flop as a desired fixed value, said second flip-flop serving as said indefinite state control flip-flop, outputting the other input value to said logic gate, the other input value preventing the output of said circuit with the logical output value thereof not fixed during the test from being output from said logic gate.

18. The method according to 10, wherein the test is conducted by inputting to a first flip-flop an output of a circuit with an output logic value not fixed during the test through a selection circuit, for latching, and reading out data latched by said first flip-flop; and
wherein, for conducting the test, a selection signal of said selection circuit is latched by a second flip-flop serving as said indefinite state control flip-flop, for outputting the selection signal, as a desired fixed value, the selection signal preventing the output of said circuit with the logical output value thereof not fixed during the test from being selected by said selection circuit, for output.
